(19) United States
(12) Patent Application Publication
(10) Pub. No.: US 2015/0115220 A1
(43) Pub. Date: Apr. 30, 2015

(54) (Al, In, Ga, B)N DEVICE STRUCTURES ON A PATTERNED SUBSTRATE

(71) Applicant: THE REGENTS OF THE UNIVERSITY OF CALIFORNIA, Oakland, CA (US)

(72) Inventors: Michael Iza, Goleta, CA (US); James S. Speck, Santa Barbara, CA (US); Shuji Nakamura, Santa Barbara, CA (US); Steven P. DenBaars, Goleta, CA (US)

(73) Assignee: THE REGENTS OF THE UNIVERSITY OF CALIFORNIA, Oakland, CA (US)

(21) Appl. No.: 14/511,966

(22) Filed: Oct. 10, 2014

Related U.S. Application Data
(60) Provisional application No. 61/896,795, filed on Oct. 29, 2013.

(51) Int. Cl. H01L 33/12; H01L 33/00; H01L 33/42; H01L 33/06; H01L 33/32

(52) U.S. Cl. CPC H01L 33/12; H01L 33/06; H01L 33/32; H01L 33/42; H01L 33/007; H01L 2933/0016
USPC 257/13; 438/47

(57) ABSTRACT

A nitride light emitting diode comprising at least one nitride-based active region formed on or above a patterned substrate, wherein the active region is comprised of at least one quantum well structure; and a nitride interlayer, formed on or above the active region, having at least two periods of alternating layers of InₓGa₁₋ₓN and In_{y}Ga_{1-y}N, where 0<x<1, 0≦y<1 and x≠y.

### CROSS REFERENCE TO RELATED APPLICATIONS

This application claims the benefit under 35 U.S.C. Section 119(e) of the following co-pending and commonly-assigned application:

U.S. Provisional Application Ser. No. 61/896,795, filed on Oct. 29, 2013, by Michael Iza, James S. Speck, Shuji Nakamura, and Steven P. DenBaars, entitled “(Al, In, Ga, B)N DEVICE STRUCTURES ON A PATTERNED SUBSTRATE,” attorneys' docket number 30794.535-US-P1 (2014-309-1);

which application is incorporated by reference herein.

### BACKGROUND OF THE INVENTION

1. Field of the Invention

This invention relates to nitride-based device structures on patterned substrates, such as nitride-based light emitting diode (LED) structures on patterned substrates, having enhanced performance.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The usefulness of gallium nitride (GaN), and its ternary and quaternary compounds incorporating aluminum and indium (AlGaN, InGaN, AlInGaN), has been well established for fabrication of visible and ultraviolet optoelectronic devices and high-power electronic devices. These devices are typically grown epitaxially using growth techniques including molecular beam epitaxy (MBE), metalorganic chemical vapor deposition (MOCVD), and hydride vapor phase epitaxy (HVPE).

Nitride-based optoelectronic devices began their quick ascent into commercialization with the advent of the use of a thin nucleation layer prior to the deposition of high quality GaN. This technique is employed due to the lack of a native substrate available for GaN growth. Later techniques, such as the development of p-type GaN by magnesium (Mg) doping followed by high temperature anneal also proved vital. However, the development of using InGaN as the active layer for short wavelength devices allowed nitride-based light emitting diodes (LEDs) and laser diodes (LDs) to overtake many other research ventures and has now become the dominant material system used for visible light semiconductor applications.

The external quantum efficiency or total efficiency (η_{L}) of LEDs can be defined by the following equation:

η_{L}=ηᵢₙₜηᵢₙⱼηₑₓₜ,

where the extraction efficiency, ηₑₓₜ, is defined as the amount of photons extracted, the injection efficiency, ηᵢₙⱼ, is defined as the amount of carriers injected into the active region of the device, and the internal quantum efficiency, ηᵢₙₜ, is defined as the amount of photons generated in the active region of the device. The internal quantum efficiency of a device can be maximized by reducing the number of non-radiative centers, such as defects and impurities. The internal quantum and injection efficiency of blue nitride-based LEDs have already been improved to a high level by optimizing the deposition conditions of the device layers. Therefore, further improvement in external efficiency of a device would require improvement in the extraction efficiency.

The extraction efficiency of nitride-based devices grown on sapphire is hampered by the difference in the refractive index between nitride films and sapphire. This refractive difference, in turn, causes internal reflections which can “trap” the light generated in the active region. Therefore, most of the light that is generated propagates through the nitride film and cannot be used as useful light.

One approach to improve light extraction from nitride devices is to use a patterned substrate on which the device is subsequently grown. A patterned substrate is defined as any substrate which has been processed to produce surface features which include but are not limited to: stripes, semicircles, pyramids, mesas of different shapes, et cetera. The pattern on the substrate aids in extracting the light emission from the active region of the device by the suppression of light interference. Early work of growth on patterned sapphire wafers by Tadatomo et al. initially tried to reduce the dislocation density of the nitride film by growing on patterned grooves or stripes along different crystal growth directions [1]. This was done in order to avoid a two step growth procedure commonly referred to as Lateral Epitaxial Overgrowth (LEO), which uses a patterned SiO₂ stripe deposited atop an as grown nitride film in order to reduce the dislocation density of the nitride film grown atop the stripes. The LEO process is cumbersome due to the fact that the wafer must be removed from the reactor in order to deposit the SiO₂ stripes and then re-introduced into the reactor for regrowth of nitride films atop the patterned nitride film. Thus, the advantage of growing on a patterned substrate is that the growth can be performed in one deposition step as compared to the two steps of the LEO process.

Further improvements of LED devices grown on patterned substrates showed enhanced light extraction by use of various types of pattern designs [2]. These devices exhibited increased output powers and luminous efficiency as compared to LED devices grown on non-patterned substrates. However, these devices employed the use of a standard LED structure. A standard LED structure is described as a structure comprising a sapphire (Al₂O₃) or silicon carbide (SiC) substrate, a buffer made of GaN or AlGaN, an n-contact layer made of GaN doped with silicon (Si), an active layer made of a single quantum well (QW) or multiple quantum wells (MQW) containing InGaN, an electron blocking layer (EBL) made of AlGaN, and a p-contact layer made of GaN doped with magnesium. This device structure was shown to work well at a forward current of 20 mA, with a light emission at 450 nm, and an output power of 10-15 mW.

Although this standard device structure has worked well for non-patterned substrates, this standard structure has exhibited detrimental performance in output power at equivalent drive currents when used with a patterned substrate. Thus, there is a need for improved device structures in order to increase performance of nitride-based LEDs deposited on patterned substrates. The present invention addresses this need by the use of a device structure which includes a nitride-based interlayer located adjacent to the active region of the device.

As stated previously, the current technology used in device structures of nitride LEDs on patterned substrates does not employ the use of a nitride-based interlayer. The present invention allows for the realization of high output power LEDs grown on patterned substrates through the use of a nitride interlayer. Although the use of a nitride interlayer has been shown to enhance the output power of LEDs grown on conventional non-patterned substrates, a scientific consensus on why this occurs has not been reached [3].

The present invention distinguishes itself from the above-mentioned previous device designs by the use of a nitride interlayer on a patterned substrate in order to improve the performance of light emitting devices. As a result, there is a need for improved device design structures on patterned substrates, wherein the device structure minimizes the deleterious effects present in conventional light emitting device structures deposited on patterned substrates. The present invention satisfies this need.

### SUMMARY OF THE INVENTION

To overcome the limitations in the prior art described above, and to overcome other limitations that will become apparent upon reading and understanding the present specification, the present invention discloses a nitride light emitting diode comprising: at least one nitride-based active region formed on or above a patterned substrate, wherein the active region is comprised of at least one quantum well structure; and a nitride interlayer, formed on or above the active region, having at least two periods of alternating layers of InₓGa₁₋ₓN and In_{y}Ga_{1-y}N, where 0<x<1, 0≦y<1 and x≠y.

The object of this invention is to enhance the light emitting output power of nitride light emitting devices, such as LEDs, which incorporate a patterned substrate. Improving the light emission efficiency leads to an improvement in the electronic efficiency characteristics of the nitride light emitting semiconductor and, in turn, can lead to the expansion of nitride semiconductor device applications into various commercial products.

Another object of the present invention is to enhance the light output power characteristics by drastically improving the properties of the active layer of a multiple quantum well structure grown on patterned substrates. This improvement can lead to the expansion of the use of patterned substrates, which have been shown to improve the light extraction of LED devices.

The first nitride semiconductor device (embodiment) of the present invention comprises a patterned substrate and incorporates a nitride interlayer containing at least some indium. This nitride interlayer can be located on any part of the device, preferably located on or above the active region of the device. It is also noted that the active layer is made of a nitride semiconductor containing at least some indium, preferably made of InGaN having a single or multiple quantum well.

Further, the first nitride semiconductor device of the present invention comprises an p-region having a plurality of nitride semiconductor films on a patterned substrate. At least one of the nitride semiconductor layers of the p-region has a p-side multi-film layer, comprised of alternating first nitride semiconductor films containing indium and second nitride semiconductor films having a different composition from the first nitride semiconductor films. Each of the first nitride semiconductor films and each of the second nitride semiconductor films are laminated alternately, and at least one of the first nitride semiconductor films and the second nitride semiconductor films have a thickness less than 100 Angstroms, with a total (multi-layer) film thickness of less than 300 nm. These first and second alternating layers will henceforth be referred to as the nitride interlayer film.

Further, in the first nitride semiconductor device, the nitride interlayer film can alternatively be comprised of a single nitride film, containing at least some indium, with a total thickness of less than 300 nm.

In the first nitride semiconductor device of the present invention, it is preferable that the nitride interlayer film is made of InₓGa₁₋ₓN (0<x<1), preferably x<0.3, and more preferably x=0.05.

In the first nitride semiconductor device of the present invention, it is preferable that the nitride interlayer film is made of alternating layers of InₓGa₁₋ₓN (0<x<1) and In_{y}Ga_{1-y}N (0≦y<1, y<x), preferably with x<0.3 and y<0.3, and more preferably with x=0.05 and y=0.

Further, in the first nitride semiconductor device of the present invention, the first nitride semiconductor films may differ in thickness from each other, and/or the second nitride semiconductor films may differ in thickness from each other. Thus, where the multi-film layer is alternately laminated with a plurality of first and second nitride semiconductor films, the two first (second) nitride semiconductor films sandwiching a second (first) nitride semiconductor film may have different thickness from each other.

Further, in the first nitride semiconductor device of the present invention, the first nitride semiconductor films may differ in Group III element content from each other, and/or the second nitride semiconductor films may differ in Group III element content from each other. Thus, where the multi-film layer is alternately laminated with a plurality of first and second nitride semiconductor films, the two first (second) nitride semiconductor films sandwiching a second (first) nitride semiconductor film may have different composition ratio of Group III element(s).

Further, in the first nitride semiconductor device of the present invention, the p-side nitride interlayer film may be spaced away from the active layer, but preferably is formed in contact with or above the active layer in order to improve the output power characteristics.

Further, in the first nitride semiconductor device of the present invention, both the first nitride semiconductor films and the second nitride semiconductor films are doped with an impurity, preferably magnesium. However, the films may also be undoped. The term of “undoped” represents the status of not being doped intentionally, including where the impurity diffuses from the adjacent nitride semiconductor layers according to the present invention. The impurity concentration due to such diffused impurity often has a gradient concentration in the layers.

Further, in the first nitride semiconductor device of the present invention, the p-type impurity is doped in any of the first nitride semiconductor films and the second nitride semiconductor films. This is referred to as modulation doping, and by being modulation doped, the output can also be improved. It is to be noted that the p-type impurity can be selected from elements such as magnesium and oxygen (O), and preferably magnesium is used for the p-type impurity.

Further, in the first nitride semiconductor device of the present invention, the p-type impurity is doped in both the first nitride semiconductor films and the second nitride semiconductor films. Where the p-type impurity is doped, the concentration is adjusted to be 5×10²¹/cm³ or less, and preferably 1×10²⁰/cm³ or less. Where it is more than 5×10²¹/cm³, the nitride semiconductor film has a poor crystal quality so that the output tends to be reduced. This is also adapted for the case where modulation doping is used.

Further objectives of the present invention are to improve the light output power of the active region on patterned substrates and to enhance the light extraction efficiency of light emitting diodes through the use of a Transparent Conducting Oxide (TCO) for the p-contact layers. The p-contact layers are typically comprised of a plurality of thin metallic layers containing nickel and/or gold. The typical thickness of these layers is less than 20 nm. Although these layers can form ohmic contacts to p-type GaN, they have also been shown to absorb some of the light emitted from the device, thereby drastically decreasing the total efficiency of the device.

The second nitride semiconductor device (embodiment) is structured in order to enhance the light extraction efficiency of the device, thereby improving the total efficiency of the device. The second nitride semiconductor device of the present invention comprises a combination of the first device as stated in the above description, with the addition of a TCO film laminated atop the p-type nitride film. In addition, the second nitride semiconductor device is further comprised of a TCO located adjacent to the p-type nitride in order to serve as a transparent contact film. The TCO can be comprised of a transparent conducting oxide such as zinc oxide (ZnO) or indium tin oxide (ITO)

Further, in the TCO of the second device of the present invention, the TCO films and the second nitride semiconductor films are not doped with an impurity. The term “undoped” represents the status not being doped intentionally, including where the impurity is diffused from the adjacent nitride semiconductor layers according to the present invention. The impurity concentration due to such diffused impurity often has a gradient concentration in the layers.

Further, in the TCO of the second device of the present invention, the TCO films can be comprised of multiple layers of various compositions.

Further, the TCO of the second device can be patterned or shaped in order to enhance light extraction.

Another object of this invention is to reduce the forward voltage, V_{f}, of a light emitting diode device on a patterned substrate with a transparent conducting oxide, through the use of a tunnel junction layer located between the p-type semiconductor and the TCO, in the third nitride device (embodiment) of the present invention.

Further, the tunnel junction layer may comprise a nitride layer containing at least some gallium. This nitride layer can be unintentionally doped, but is preferably doped with an n-type impurity, such as silicon, with doping concentration greater than 1×10¹⁸/cm³, and more preferably greater than 5×10¹⁹/cm³.

Further, the tunnel junction layer may comprise a nitride layer containing at least some indium. This nitride layer can be unintentionally doped, preferably doped with an n-type impurity, such as silicon, with doping concentration greater than 1×10¹⁸/cm³, and more preferably 5×10¹⁹/cm³.

Another object of this invention is to increase the light extraction of the LED by patterning or shaping the TCO, as described by the fourth and fifth nitride semiconductor devices (embodiments) of the present invention. The shaping can be achieved through physical and/or chemical processes and may comprise of various shapes or sizes.

The first, second, third, fourth, and fifth devices (embodiments) of the present invention describe nitride light emitting device structures incorporating a nitride interlayer deposited on a patterned substrate which can also be combined with a patterned or non-patterned TCO and/or a tunnel junction. The patterned substrate may comprise of any pattern, shape or design. The structure may further comprise of any device or structure grown atop the nitride film which incorporates a nitride interlayer on a patterned substrate and which may also incorporate a TCO and/or a tunnel junction.

Further, the present invention also includes any combination of the first, second, third, fourth, and fifth devices which incorporates a nitride interlayer grown on a patterned substrate, as described above for the first device.

The nitride interlayer film may comprise multiple layers having varying or graded compositions, a heterostructure comprising layers of dissimilar (Al, Ga, In, B)N composition, or one or more layers of dissimilar (Al, Ga, In, B)N composition. The nitride interlayer film may comprise of unintentionally doped or intentionally doped layers, with elements such as iron, magnesium, silicon, oxygen, carbon, and/or zinc. The nitride interlayer film may be grown using deposition methods comprising HVPE, MOCVD or MBE.

The structure may further comprise the nitride interlayers grown in any crystallographic nitride direction, such as on a conventional c-plane oriented nitride semiconductor crystal, or on a nonpolar plane, such as a-plane or m-plane, or on any semipolar plane.

The present invention also discloses a device having enhanced properties using the above described structures.

### BRIEF DESCRIPTION OF THE DRAWINGS

Referring now to the drawings in which like reference numbers represent corresponding parts throughout:

FIG. 1 is a cross-sectional schematic of the first nitride semiconductor device of the present invention, comprising of a patterned substrate and incorporating a nitride interlayer containing at least some indium.

FIG. 2 is a cross sectional schematic of the second nitride semiconductor device of the present invention, comprising of a combination of the first device, as shown in FIG. 1, with the addition of a TCO film laminated atop the p-type nitride film.

FIG. 3 is a cross sectional schematic showing the use of a tunnel junction layer located between the p-type semiconductor and the TCO.

FIG. 4 is a cross sectional schematic of an LED showing patterning or shaping of the TCO.

FIG. 5 is a cross sectional schematic of another LED showing patterning or shaping of the TCO.

FIG. 6 is a flowchart illustrating the process steps for fabricating a device according to the embodiments of the present invention.

FIG. 7 shows the output power measured for LEDs with and without a superlattice containing some indium, on both patterned and non-patterned sapphire substrates.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes nitride light emitting device structures incorporating a nitride interlayer deposited on a patterned substrate via MOCVD. The use of nitride-based interlayer structures incorporated into light emitting devices offers a means of improving the nitride light emitting device performance.

Current nitride light emitting device structures deposited on patterned substrates are comprised of structures without a nitride interlayer. These structures show a drastic degradation in device performance, such as power output at a constant current. Nitride light emitting device structures incorporating a nitride interlayer provide a means of enhancing the performance of nitride LEDs by greatly enhancing the device output power at constant current. The present invention provides a means of enhancing nitride device performance of nitride LEDs deposited on patterned substrates.

Technical Description

### First Embodiment

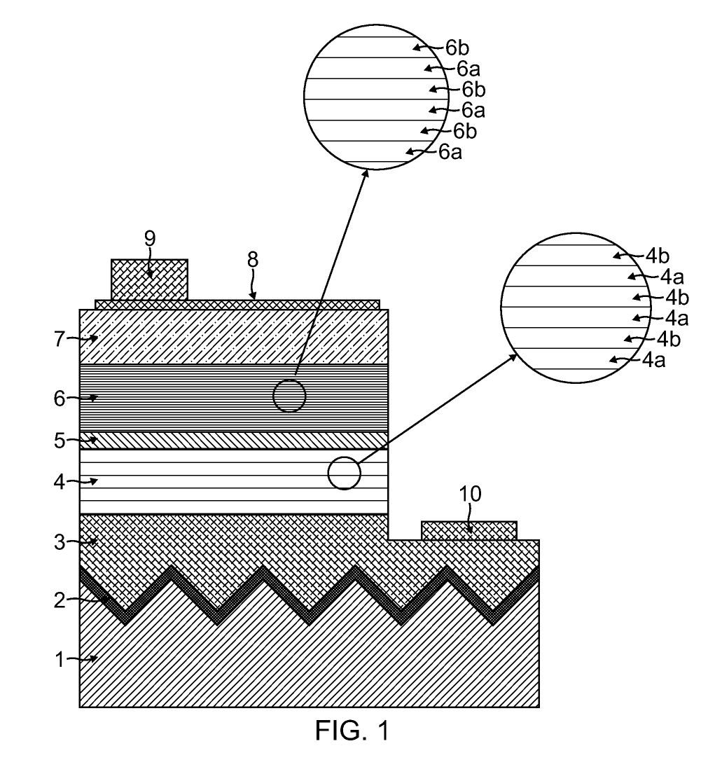

FIG. 1 is a schematic sectional view showing the structure of a nitride semiconductor device (an LED device) according to the first embodiment of the present invention. This LED is comprised of a patterned sapphire substrate 1, and deposited successively in the following order on the substrate 1: a first buffer layer 2 made of GaN (closest to the substrate 1 surface), an n-contact layer 3 made of GaN doped with silicon, an active layer 4 comprising a multiple quantum well structure made of InGaN/GaN, a p-side AlGaN electron blocking layer 5 doped with magnesium, a p-side multi-layer film 6 comprising a nitride interlayer made of an InGaN/GaN superlattice structure doped with magnesium, a p-contact layer 7 comprising GaN doped with magnesium, a thin transparent p-contact layer 8, and a thick p-pad layer 9 that is the furthest from the substrate 1 surface.

As noted above, the LED device according to the first embodiment has a nitride-based active region 4 comprised of at least one quantum well structure sandwiched between an n-region including the first buffer layer 2 and the n-contact layer 3, and a p-region including the p-side AlGaN electron blocking layer 5, the p-side multi-layer film 6 comprising the nitride interlayer made of the InGaN/GaN superlattice structure and the p-contact layer 7.

As shown in a magnified callout in FIG. 1 labeled with 4a and 4b, the active layer 4 of the multiple quantum well structure was grown by laminating alternately barrier layers 4a and well layers 4b, in the order of barrier layer 4a, well layer 4b, barrier layer 4a, etc., and finishing on a barrier layer 4a. The active layer 4 was grown by laminating the barrier layer 4a first, but may be grown by laminating the well layer 4b first and also last. The active layer 4 may be grown by laminating in the well layer 4b first and the barrier layer 4a last, or the order may begin with the barrier layer 4a and end with the well layer 4b. Thus, the order of depositing the barrier layers 4a and well layers 4b is not specifically limited to a particular order. In addition, the number of barrier layers 4a and well layers 4b is not specifically limited to a particular number.

In one embodiment, the active layer 4 is comprised of seven barrier layers 4a and six well layers 4b and has a total thickness of 170 nm. The well layers 4b have a thickness of not greater than 100 Angstroms, preferably not greater than 70 Angstroms, and more preferably not greater than 50 Angstroms, wherein a thickness of greater than 100 Angstroms may make it difficult to increase the output of the device. On the other hand, the barrier layers 4a have a thickness of not greater than 300 Angstroms, preferably not greater than 250 Angstroms, and most preferably not greater than 200 Angstroms.

The nitride semiconductor device according to the first embodiment includes the p-side multi-film layer 6, also known as a nitride interlayer 6, above the AlGaN electron blocking layer 5, depositing, as shown in a magnified callout in FIG. 1 labeled with 6a and 6b, a first nitride semiconductor film 6a containing In and a second nitride semiconductor film 6b of a composition different from that of the first nitride semiconductor film 6a. Specifically, the nitride interlayer 6 is comprised of at least two periods of alternating layers of InₓGa₁₋ₓN and In_{y}Ga_{1-y}N, where 0<x<1, 0≦y<1 and x≠y. In one embodiment, the bandgap of the quantum well structure of the active region 4 is less than the bandgap of the nitride interlayer 6.

The p-side multi-film layer 6 includes at least one of each of the first nitride semiconductor film 6a and the second nitride semiconductor film 6b, and preferably includes more than three films in total and more preferably at least two of each film 6a and 6b, i.e., at least four films in total. For example, the two periods of alternating layers may comprise at least two first nitride layers interleaved with at least two second nitride layers, wherein the first layers contain indium and the second layers contain substantially no indium.

Thus, FIG. 1 shows that the multi-film layer 6 is a superlattice comprised of a sequence of first nitride semiconductor films 6aᵢ interleaved with a sequence of second nitride semiconductor films 6bᵢ, where i is an integer indexing the number of films. Where the properties of the individual films 6aᵢ (6bᵢ) are similar, the films will generally be referred to as 6a (6b).

Where the p-side multi-film layer 6 is formed above the active layer 4, as is shown in FIG. 1, one of the nitride semiconductor films 6a and 6b which is held in contact with the p-side AlGaN electron blocking layer 5 may be either the first nitride semiconductor film 6a or the second nitride semiconductor film 6b.

The depositing sequence of the nitride films 6a and 6b in the p-side multi-film layer 6 may be arbitrarily chosen. Also, although the p-side multi-film layer 6 is formed in direct contact with the p-side AlGaN electron blocking layer 5 in the illustrated embodiment, another layer made of a p-type nitride semiconductor may intervene between the p-side multi-film layer 6 and the active layer 4.

At least one first nitride semiconductor film 6a, and at least one second nitride semiconductor film 6b, is designed to have a film thickness not greater than 100 Angstroms, preferably not greater than 70 Angstroms, and more preferably not greater than 50 Angstroms. When the films 6a and 6b have a thickness within the above-mentioned range, since the two periods of alternating layers 6a and 6b have a thickness smaller than a critical elastic thickness of a nitride, so that the nitride interlayer 6 acts as buffer layer, the crystal quality of the first or second nitride semiconductor films deposited on such thin film can be improved, thereby improving the crystal quality of the p-side multi-film layer 6 as a whole, to increase the output capability of the device.

At least one first nitride semiconductor film 6a is made of a nitride semiconductor containing In, preferably a ternary compound which is expressed by the formula InₓGa₁₋ₓN (0<x<1), wherein x is preferably not greater than 0.5 and more preferably not greater than 0.1.

On the other hand, at least one second nitride semiconductor film 6b may be made of any suitable nitride semiconductor, provided that the latter is different from that used for the at least one first nitride semiconductor film 6a. In order, however, for the at least one second nitride semiconductor film 6b to retain an excellent crystal quality, a nitride semiconductor of a binary or ternary compounds having a bandgap higher than the at least one first nitride semiconductor film 6a has to be developed, although the present invention is not exclusively limited to these compounds. If among the various nitride semiconductors, GaN is chosen as a material for the at least one second nitride semiconductor film 6b, a multi-film layer having an excellent crystal quality can be formed. Accordingly, the use of InₓGa₁₋ₓN, wherein x is not greater than 0.5, for the at least one first nitride semiconductor film 6a, and GaN for the at least one second nitride semiconductor film 6b is a preferred combination of materials.

In one embodiment, any one of the first and second nitride semiconductor films 6a and 6b has a film thickness not greater than 100 Angstroms, preferably not greater than 70 Angstroms and more preferably not greater than 50 Angstroms. Selection of the film thickness not greater than 100 Angstroms for each of the first and second nitride semiconductor films 6a and 6b means that the respective nitride semiconductor films 6a and 6b can have a film thickness not greater than the critical elastic thickness and, therefore, a nitride semiconductor having an excellent crystal quality can be grown as compared with the case in which it is grown into a thick film. Selection of the film thickness not greater than 70 Angstroms is effective in creating the multi-film layer 6 into a superlattice structure and, therefore, can improve the crystal quality of the growing film.

In another embodiment, the first nitride semiconductor films 6a may have different thicknesses, and the second nitride semiconductor films 6b may have different thicknesses. For example, at least one of the first (second) nitride semiconductor films 6aᵢ (6bᵢ) can have a film thickness different from that of the next neighboring first (second) nitride semiconductor films 6aᵢ₋₁ (6bᵢ₊₁) and 6aᵢ₊₁ (6bᵢ₊₁) (i.e., the thickness of the film 6aᵢ can be different from the thicknesses of the films 6aᵢ₋₁(6bᵢ₋₁) and 6aᵢ₊₁(6bᵢ₊₁), which are respectively below and above the film 6aᵢ (6bᵢ) in the sequence of first (second) nitride semiconductor films). By way of further example, assuming that the first nitride semiconductor film 6a is made of InGaN and the second nitride semiconductor film 6b is made of GaN, the InGaN layer 6aᵢ intervening between the neighboring GaN layers 6bᵢ and 6bᵢ₋₁ may have a varying film thickness either increasing or decreasing as the distance from the layer 6aᵢ to the active layer 4 increases or decreases, in order to vary a refractive index of the alternating layers. In so doing, the multi-film layer 6 can have a varying index of refraction with the nitride semiconductor films 6aᵢ and 6bᵢ having different indexes of refraction and, consequently, the multi-film layer 6 can exhibit substantially the same effects as those of a grading composition nitride semiconductor layer. Accordingly, in a semiconductor device, such as a semiconductor laser of a type requiring the use of a beam waveguide, the multi-film layer 6 can provide the beam waveguide to adjust the mode of the laser beam.

Also, at least one of the first (second) nitride semiconductor films may contain a composition of Group III elements that is different from the composition in the next neighboring first (second) nitride semiconductor film. For example, the composition of the film 6aᵢ (6bᵢ) can be different from the composition of the films 6aᵢ₋₁(6bᵢ₋₁) and 6aᵢ₊₁(6bᵢ₊₁) which are respectively below and above the film 6aᵢ (6bᵢ) in the sequence of first (second) nitride semiconductor films. By way of further example, assuming that the first nitride semiconductor films 6aᵢ are made of InGaN and the second nitride semiconductor films 6b are made of GaN, the Indium composition, i.e., the amount of Indium, contained in the InGaN layer 6aᵢ intervening between the neighboring GaN layers 6bᵢ and 6bᵢ₋₁ may be increased or decreased as the distance from 6aᵢ to the active layer 4 increases or decreases, in order to vary a refractive index of the alternating layers. In such a case, as is the case with the use of the differing film thicknesses as discussed above, the multi-film layer 6 can have a varying index of refraction with the nitride semiconductor films 6aᵢ and 6bᵢ having different indexes of refraction and, consequently, the multi-film layer 6 can exhibit substantially the same effects as those of a grading composition nitride semiconductor layer. It is to be noted that the index of refraction tends to decrease with decreasing amount of In used.

In another embodiment, the first and second nitride semiconductors layers 6a and 6b can be made of the same semiconductor material, thus creating a single layer of a similar total thickness to that of the multi-film layer 6 comprised of films 6a and 6b described above. The nitride multi-film layer 6 is made of a nitride semiconductor containing In, preferably a ternary compound which is expressed by the formula InₓGa₁₋ₓN (0<x<1), wherein x is preferably not greater than 0.5 and more preferably not greater than 0.1. This thick film enables a simpler method of depositing the film 6 since it only incorporates a single layer as compared to the multi-layer film comprised of films 6a and 6b.

Again, in the practice of the first embodiment, one or both of the first and second nitride semiconductor films 6a and 6b may be either undoped or doped with p-type impurity. To enhance the crystal quality, the first and second nitride semiconductor films 6a and 6b are preferably undoped, but may be modulation doped, or both of the first and second nitride semiconductor films 6a and 6b may be doped with the p-type impurity. Where both of the first and second nitride semiconductor films 6a and 6b are doped with the p-type impurity, the concentration of the p-type impurity in the one or more first nitride semiconductor films 6a may be different from the concentration in the one or more second nitride semiconductor films 6b.

In another embodiment, the transparent p-electrode 8 is formed on approximately the entire top surface of the p-contact layer 7, and a p-pad electrode 9 for bonding is formed on a portion of the p-electrode 8. Also, the emitting device has a portion where a surface of the n-side nitride semiconductor layer 3 is exposed and an n-electrode 10 is formed thereon.

### Second Embodiment

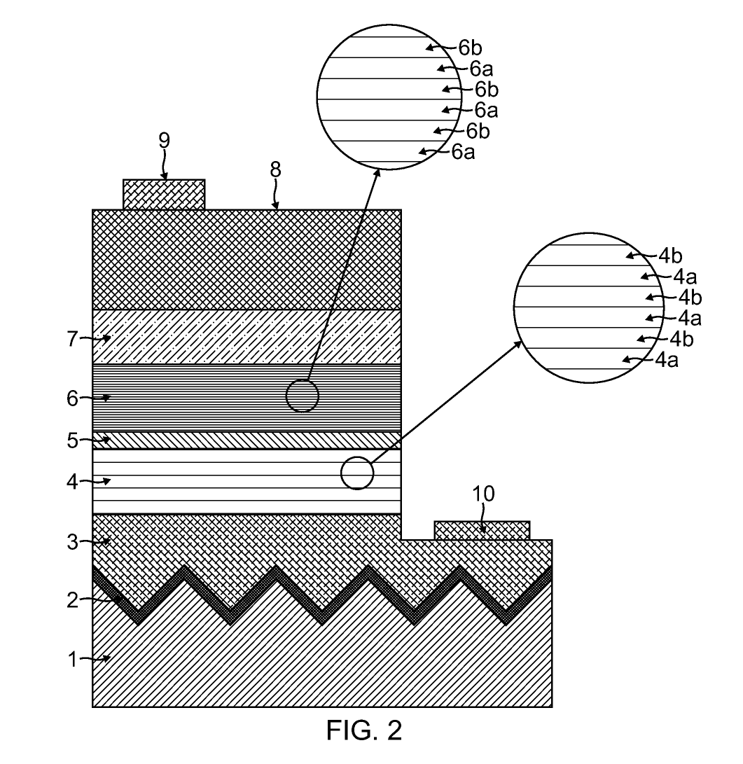

The nitride semiconductor light emitting device according to a second embodiment, as shown in FIG. 2, has the same structure as the first embodiment, except that the transparent p-contact layer 8 in the second embodiment is comprised of a novel p-contact, such as a TCO, thereby substituting the thin semi-transparent p-electrode layer 8 described in the first embodiment.

In this embodiment, the nitride interlayer 6 is formed between an n-type nitride region and a p-type nitride region, and the TCO layer 8 is formed on or above the p-type nitride region, wherein the TCO oxide layer 8 is a p-type contact to the p-type nitride region.

Specifically, the TCO may be comprised of elements such as ZnO or ITO.

These layers can be deposited in-situ, such as in an MOCVD reactor, or can be subsequently laminated in a separate deposition process. The TCO can also be structurally bonded using an appropriate process.

Also, the TCO film or films may comprise a plurality of different layers and compositions. They can also be unintentionally doped or intentionally doped with various elements in order to tailor the films' properties, such as electrical conductivity and structural composition.

The TCO films may also comprise various thicknesses.

### Third Embodiment

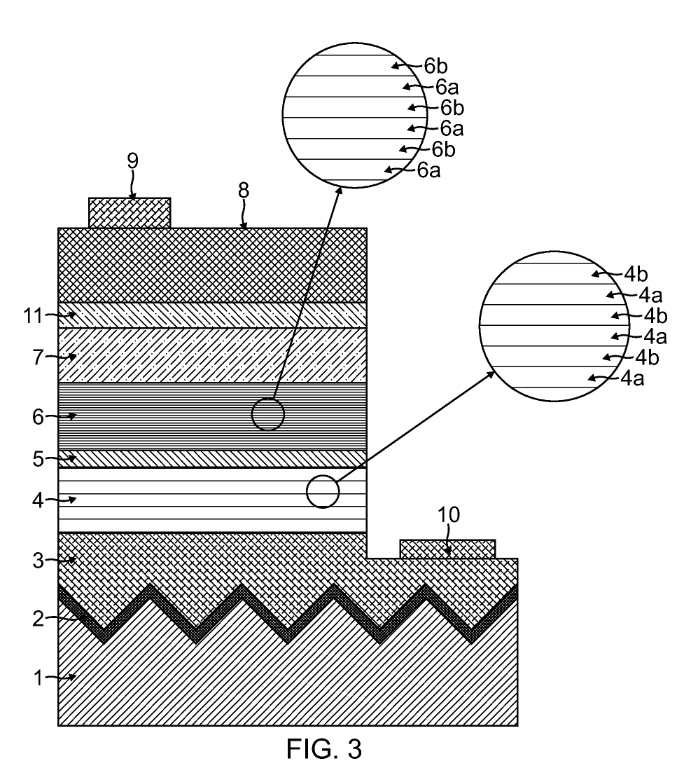

The nitride semiconductor light emitting diode according to a third embodiment, as shown in FIG. 3, has the same structure as the second embodiment, except that a tunnel junction layer 11 is laminated between the p-type GaN contact layer 7 and the TCO 8. Specifically, the tunnel junction layer 11 is a nitride-based tunnel junction layer 11 formed adjacent to the p-type nitride layer 7 and the TCO 8.

In this regard, the tunnel junction layer 11 may be comprised of a nitride semiconductor which is intentionally doped with an n-type or p-type impurity, such as elements of silicon or magnesium, in order to control the conductivity of the layer. The tunnel junction layer 11 can be comprised of various thicknesses and compositions. It can also be comprised of a plurality of different layers. It can also be doped with graded compositions or modulation doped.

### Fourth Embodiment

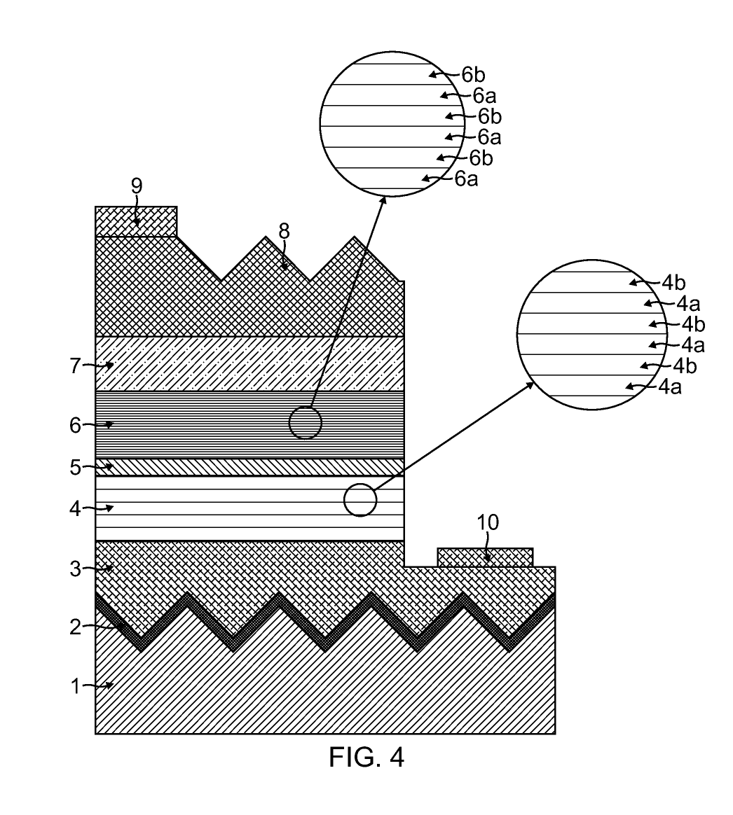

The nitride semiconductor light emitting diode according to a fourth embodiment, as shown in FIG. 4, has the same structure as the second embodiment, except that the TCO 8 is patterned or shaped in order to enhance light extraction from the device. The patterning or shaping can be achieved through physical or chemical processes. The patterning or shaping can also be comprised of various patterns, shapes and sizes.

### Fifth Embodiment

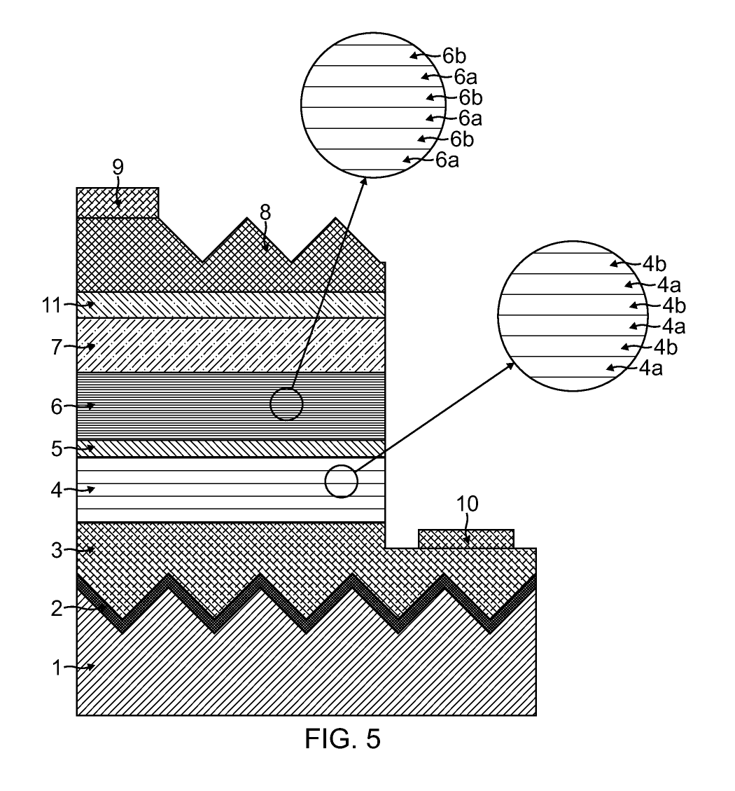

The nitride semiconductor light emitting diode according to a fifth embodiment, as shown in FIG. 5, has the same structure as the third embodiment, except that the TCO 8 is patterned or shaped in order to enhance light extraction from the device. The patterning or shaping can be achieved through physical or chemical processes. The patterning or shaping can also be comprised of various patterns, shapes and sizes.

Process Steps

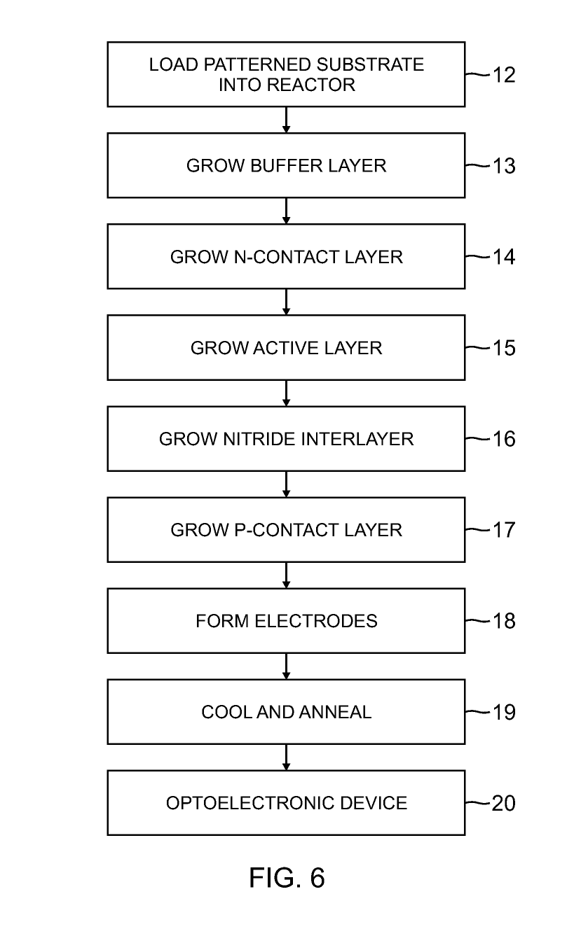

FIG. 6 is a flowchart illustrating a method for fabricating a device according to an embodiment of the present invention, wherein the device structure is illustrated by reference to FIG. 1.

First, a patterned substrate 1 was loaded in a reactor and cleaned, in Block 12. In the first example, a patterned sapphire substrate (C-face) was set in the MOVPE reactor and the temperature of the substrate was increased to 1150° C. with hydrogen flow to clean the substrate. Instead of a C-face sapphire substrate, the substrate 1 may be a patterned sapphire substrate having its principal surface represented by an R- or A-face, a patterned insulating substrate of, for example, spinel (MgAl₂O₄), or a patterned semiconductor substrate made of, for example, SiC (including 6H, 4H or 3C), Si, ZnO, GaAs, GaN.

Subsequently to the increased temperature of Block 12, the temperature was decreased to 570° C. and a first buffer layer 2 made of GaN, which had a thickness of about 200 Angstroms was grown on the substrate 1, using hydrogen as a carrier gas, and ammonia and TMG (trimethylgallium) as material gases, in Block 13. Such a buffer layer 2 that is grown at a low temperature may be omitted, depending on the kind of the substrate, the growing method, etc.

After growing the buffer layer 2 in Block 13, only TMG was stopped and the temperature was increased to 1185° C., in Block 14. An n-contact layer 3, made of GaN doped with Si to 3×10¹⁹/cm³ and having a thickness of 4 μm, was grown using ammonia and TMG as material gases in the same way as in the previous step, and silane gas as an impurity gas. This n-contact layer 3 may be made of InₓAl_{y}GaN (0≦x, 0≦y, x+y<1). The composition is not specifically limited to that composition, but preferably may be GaN and AlₓGa₁₋ₓN (wherein x is not greater than 0.2). In such a case, a nitride semiconductor layer having a minimized crystal defect can easily be obtained.

The thickness of the n-contact layer 3 is not specifically limited to any thickness, but the thickness may not be smaller than 2 μm because the n-electrode is formed thereon. Moreover, the n-type impurity may be desirably doped in with a high concentration to the degree that the crystal quality of the nitride semiconductor is not deteriorated and preferably in the concentration between 1×10¹⁸/cm³ and 5×10²¹/cm³.

Next, in Block 14, a barrier layer made of undoped GaN having a thickness of 200 Angstroms was grown at 880° C., and a well layer made of undoped In_{0.4}Ga_{0.6}N which had a thickness of 25 Angstroms was grown using TMG, TMI and ammonia. An active layer 4 with a multiple quantum well structure having a total thickness of 170 nm was grown by laminating alternately seven barrier layers 4a and six well layers 4b, in the order of barrier layer 4a, well layer 4b, barrier layer 4a, etc., and finishing on a barrier layer 4a. The active layer 4 was grown by laminating the barrier layer 4a first, but may be grown by laminating the well layer 4b first and also last. The active layer 4 may be grown by laminating in the well layer 4b first and the barrier layer 4a last, or the order may begin with the barrier layer 4a and end with the well layer 4b. Thus, the order of depositing the barrier layers 4a and well layers 4b is not specifically limited to a particular order. In addition, the number of barrier layers 4a and well layers 4b is not specifically limited to a particular number.

As noted above, the well layer 4b was set to have a thickness of not greater than 100 Angstroms, preferably not greater than 70 Angstroms, and more preferably not greater than 50 Angstroms, wherein a thickness of greater than 100 Angstroms may make it difficult to increase the output of the device. On the other hand, the barrier layer 4a was set to have a thickness of not greater than 300 Angstroms, preferably not greater than 250 Angstroms, and most preferably not greater than 200 Angstroms.

Next, in Block 15, using TMG, TMA, and ammonia, a third nitride semiconductor film, made of unintentionally doped Al_{0.2}Ga_{0.8}N which had a thickness of 200 Angstroms, was grown. This AlGaN electron blocking layer 5 may be made of InₓAl_{y}GaN (0≦x, 0≦y, x+y<1). The composition is not specifically limited to this composition, but preferably may be AlₓGa₁₋ₓN (where x is not greater than 0.2).

Next, in Block 16, the temperature was increased to 880° C. and a first nitride semiconductor film (layer 6a), made of In_{0.03}Ga_{0.97}N doped with Mg to 1×10²⁰/cm³ and having a thickness of 25 Angstroms, was grown using TEG, TMI, Cp₂Mg, and ammonia. Subsequently, TMI was shut off, and a second nitride semiconductor film (layer 6b), made of GaN doped with magnesium to 1×10²⁰/cm³ having a thickness of 25 Angstroms, was grown on the first film 6a. Then, these operations were repeated and the p-side multi-film (nitride interlayer film) 6 in the form of a superlattice structure, which had a thickness of 250 nm, was formed by alternately laminating the first film 6a and the second film 6b, fifty times each, in the following order: first film 6a, second film 6b, first film 6a, and so on.

Subsequently, in Block 17, at 910° C., using TMG, ammonia and Cp₂Mg, a p-contact layer 7 was grown, made of p-type GaN doped with magnesium to 1×10²⁰/cm³ which had a thickness of 100 Angstroms. The p-contact layer 7 may also be made of InₓAl_{y}Ga_{1-x-y}N (0≦x, 0≦y, x+y≦1). The composition is not specifically limited to this composition, but preferably may be GaN. In such a case, a nitride semiconductor layer having minimized crystal defects can be obtained and an excellent ohmic contact with the p-electrode material 8 can be achieved.

Block 18 represents the p-electrode 8, p-pad 9 and n-electrode 10 being formed on the LED.

Once the reactor has cooled, the LED is removed and annealed in a hydrogen deficient atmosphere for 15 minutes at a temperature of 700° C. in order to activate the p-type GaN, in Block 19.

The end result, represented by Block 20, is an optoelectronic device, such as an LED, comprising a patterned substrate; at least one nitride-based active region formed on or above the patterned substrate, wherein the active region is comprised of at least one quantum well structure; and at least one nitride interlayer formed on or above the active region, wherein the nitride interlayer contains at least some indium.

Advantages and Improvements

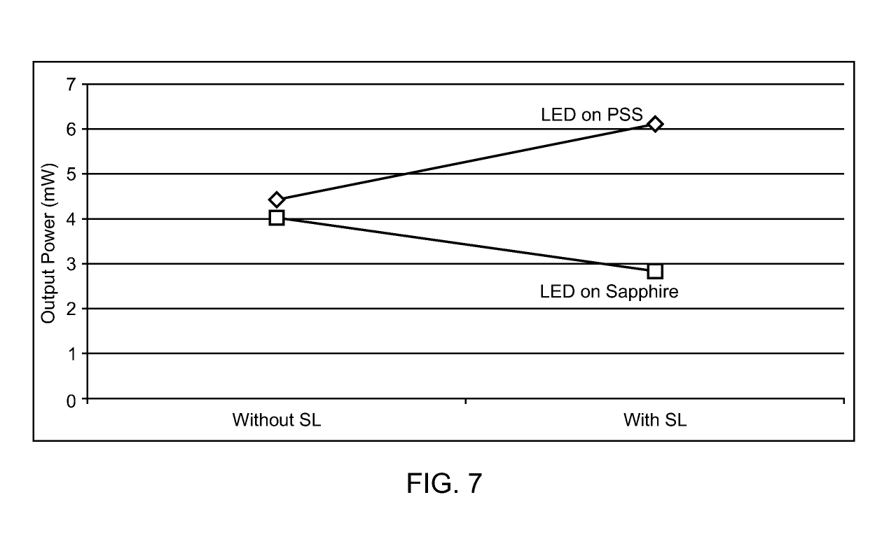

FIG. 7 shows the output power measured for LEDs with and without a superlattice containing some indium, on both patterned and non-patterned sapphire substrates. The output power of the LEDs was evaluated by measuring the light output using a silicon photo detector through the back of the substrate. This is commonly referred to as an “on-wafer” measurement. FIG. 7 indicates an increase in output power by using a superlattice, for samples on a non-patterned and a patterned sapphire substrate. However, it is also clear from the figure that the use of a superlattice on a patterned substrate leads to a significant increase in the output power of about 40%. This is in contrast to a 30% decrease in output power when a superlattice is employed on a non-patterned sapphire substrate.

Nomenclature

The terms “Group-III nitride” or “III-nitride” or “nitride” as used herein refer to any alloy composition of the (Ga, Al, In, B)N semiconductors having the formula GaₙAlₓIn_{y}B_{z}N where:

0≦n≦1, 0≦x≦1, 0≦y≦1, 0≦z≦1, and n+x+y+z=1

These terms as used herein are intended to be broadly construed to include respective nitrides of the single species, Ga, Al, In and B, as well as binary, ternary and quaternary compositions of such Group III metal species. Accordingly, these terms include, but are not limited to, the compounds of AlN, GaN, InN, AlGaN, AlInN, InGaN, and AlGaInN. When two or more of the (Ga, Al, In, B)N component species are present, all possible compositions, including stoichiometric proportions as well as off-stoichiometric proportions (with respect to the relative mole fractions present of each of the (Ga, Al, In, B)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal orientations, directions, terminations and polarities of Group-III nitrides. When identifying crystal orientations, directions, terminations and polarities using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

Many Group-III nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in Group-III nitride devices is to grow the devices along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

References

The following references are incorporated by reference herein.

[1] K. Tadatomo, H. Okagawa, Y. Ohuchi, T. Tsunekawa, T. Jyouichi, Y. Imada, M. Kato, H. Kudo, and T. Taguchi, phys. stat. sol. (a) 188, No. 1, pp. 121-125 (2001).

[2] Motokazu Yamada, Tomotsugu Mitani, Yukio Narukawa, Shuji Shioji, Isamu Niki, Shinya Sonobe, Kouichiro Deguchi, Masahiko Sano and Takashi Mukai, Jpn. J. Appl. Phys. Vol. 41 (2002) pp. L 1431-L 1433, Part 2, No. 12B, 15 Dec. 2002.

[3] Shuji Nakamura, Takashi Mukai, Masayuki Senoh, Shin-ichi Nagahama, and Naruhito Iwasa, J. Appl. Phys. Vol. 74, No. 6 (1993) pp. 3911-3915, 15 Sep. 1993.

Conclusion

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An optoelectronic device, comprising
a patterned substrate;
at least one nitride-based active region formed on or above the patterned substrate, wherein the active region is comprised of at least one quantum well structure; and
at least one nitride interlayer formed on or above the active region, wherein the nitride interlayer contains at least some indium.

2. The device of claim 1, wherein the nitride interlayer is comprised of at least two periods of alternating layers of InₓGa₁₋ₓN and In_{y}Ga_{1-y}N, where 0<x<1, 0≦y<1 and x#y.

3. The device of claim 2, wherein the two periods of alternating layers comprise at least two first layers interleaved with at least two second layers, wherein the first layers contain indium and the second layers contain substantially no indium.

4. The device of claim 2, wherein the two periods of alternating layers have a thickness smaller than a critical elastic thickness of a nitride, so that the nitride interlayer acts as a buffer layer for improving the active region's crystal quality.

5. The device of claim 2, wherein the alternating layers comprise a first layer and a second layer, and the first layer's thickness increases or decreases as a distance from the first layer to the active region increases or decreases, in order to vary a refractive index of the alternating layers.

6. The device of claim 2, wherein the alternating layers comprise a first layer and a second layer, and the first layer's indium composition increases or decreases as a distance from the first layer to the active region increases or decreases, in order to vary a refractive index of the alternating layers.

7. The device of claim 1, wherein a bandgap of the at least one quantum well structure is less than a bandgap of the nitride interlayer.

8. The device of claim 1, wherein the nitride interlayer is formed between an n-type nitride layer and a p-type nitride layer, a transparent conducting oxide layer is formed on or above the p-type nitride layer, and the transparent conducting oxide layer is a p-type contact to the p-type nitride layer.

9. The device of claim 8, wherein the transparent conducting oxide is patterned.

10. The device of claim 8, further comprising a nitride-based tunnel junction layer formed adjacent to the p-type nitride layer and the transparent conducting oxide layer.

11. A method of fabricating an optoelectronic device, comprising:
providing a patterned substrate;
forming at least one nitride-based active region, on or above the patterned substrate, wherein the active region is comprised of at least one quantum well structure; and
forming at least one nitride interlayer, on or above the active region, wherein the nitride interlayer contains at least some indium.

12. The method of claim 11, wherein the nitride interlayer is comprised of at least two periods of alternating layers of InₓGa₁₋ₓN and In_{y}Ga_{1-y}N, where 0<x<1, 0≦y<1, and x#y.

13. The method of claim 12, wherein the two periods of alternating layers comprise at least two first layers interleaved with at least two second layers, wherein the first layers contain indium and the second layers contain substantially no indium.

14. The method of claim 12, wherein the two periods of alternating layers have a thickness smaller than a critical elastic thickness of a nitride, so that the nitride interlayer acts as a buffer layer for improving the active region's crystal quality.

15. The method of claim 12, wherein the alternating layers comprise a first layer and a second layer, and the first layer's thickness increases or decreases as a distance from the first layer to the active region increases or decreases, in order to vary a refractive index of the alternating layers.

16. The method of claim 12, wherein the alternating layers comprise a first layer and a second layer, and the first layer's indium composition increases or decreases as a distance from the first layer to the active region increases or decreases, in order to vary a refractive index of the alternating layers.

17. The method of claim 11, wherein a bandgap of the at least one quantum well structure is less than a bandgap of the nitride interlayer.

18. The method of claim 11, wherein the nitride interlayer is formed between an n-type nitride layer and a p-type nitride layer, a transparent conducting oxide layer is formed on or above the p-type nitride layer, and the transparent conducting oxide layer is a p-type contact to the p-type nitride layer.

19. The method of claim 18, wherein the transparent conducting oxide is patterned.

20. The method of claim 18, further comprising a nitride-based tunnel junction layer formed adjacent to the p-type nitride layer and the transparent conducting oxide layer.
